(19) United States
(12) Patent Application Publication
(10) Pub. No.: US 2025/0279377 A1
(43) Pub. Date: Sep. 4, 2025

(54) COPPER PAD INTERCONNECT SYSTEMS AND RELATED METHODS

(71) Applicant: SEMICONDUCTOR COMPONENTS INDUSTRIES, LLC, Scottsdale, AZ (US)

(72) Inventors: Guy BRIZAR, Oosterzele (BE); Michael J. SEDDON, Gilbert, AZ (US)

(73) Assignee: SEMICONDUCTOR COMPONENTS INDUSTRIES, LLC, Scottsdale, AZ (US)

(21) Appl. No.: 19/213,279

(22) Filed: May 20, 2025

Related U.S. Application Data
(63) Continuation-in-part of application No. 18/446,127, filed on Aug. 8, 2023.

(51) Int. Cl. H01L 23/00; H01L 23/31

(52) U.S. Cl. CPC H01L 24/03; H01L 23/3192; H01L 24/04; H01L 24/05; H01L 2224/0345; H01L 2224/03452; H01L 2224/03462; H01L 2224/03464; H01L 2224/0347; H01L 2224/0361; H01L 2224/04042; H01L 2224/05005; H01L 2224/05084; H01L 2224/05147; H01L 2224/05166; H01L 2224/05181; H01L 2224/05184; H01L 2224/05541; H01L 2224/05567; H01L 2224/05582; H01L 2224/05624; H01L 2224/05639; H01L 2224/05644; H01L 2224/05655; H01L 2224/05664; H01L 2224/0569; H01L 2924/3511; H01L 2924/3512

(57) ABSTRACT

Implementations of a semiconductor device may include an interconnect that may include a tantalum layer directly coupled with a first copper layer a titanium tungsten layer directly coupled with the first copper layer; a second copper layer coupled directly with the titanium tungsten layer; and a metal layer directly coupled to the second copper layer. The device may include a gate that may include a tantalum layer directly coupled with a first copper layer; a polyimide layer directly coupled over the first copper layer; a titanium tungsten layer directly coupled over the polyimide layer; a second copper layer coupled directly with the titanium tungsten layer; and a metal layer directly coupled to the second copper layer.

### CROSS REFERENCE TO RELATED APPLICATIONS

This application is a continuation-in-part application of the earlier U.S. Utility Patent Application to Seddon et al., entitled “Copper Pad Metallization Systems and Related Methods,” application Ser. No. 18/446,127 filed Aug. 8, 2023, now pending, the disclosure of which is hereby incorporated entirely herein by reference.

### BACKGROUND

### 1. Technical Field

Aspects of this document relate generally to methods for forming electrical interconnects. More specific implementations involve electrical interconnects that include copper pads.

### 2. Background

Semiconductor packages have been devised that allow for routing of electrical signals from a semiconductor die to components of the package used to interface with a circuit board or motherboard to which the semiconductor package is attached. Semiconductor packages also have been developed that assist with protecting the semiconductor die from humidity, thermal conditions, or shock and vibration during operation and use.

### SUMMARY

Implementations of a method of forming an interconnect may include forming a barrier layer including tantalum over a metallization layer included in a semiconductor substrate; forming a first seed layer over the barrier layer; and forming a first patterned layer of photoresist including a plurality of openings over the first seed layer. The method may include forming a first copper layer by electroplating into each opening of the plurality of openings; removing the first patterned layer of photoresist; etching the first seed layer and the barrier layer; and patterning a layer of polyimide over the first copper layer to expose a copper pad and form a dielectric layer for a copper gate pad. The method includes forming a second seed layer over the layer of polyimide and the copper pad; forming a second patterned layer of photoresist including a plurality of openings over the second seed layer; and forming a second copper layer by electroplating into the plurality of openings. The method includes forming a metal layer over the second copper layer by electroplating into the plurality of openings; removing the second patterned layer of photoresist; and etching the second seed layer to form an interconnect.

Implementations of a method of forming an interconnect may include one, all, or any of the following:

The metal layer may be a silver layer.

The metal layer may be a nickel layer and the method further may include electroplating one of a gold layer, a palladium layer, or a silver layer over the nickel layer.

The method may include patterning a second layer of polyimide over the interconnect.

The barrier layer also may include tantalum nitride.

The first seed layer may include copper and the second seed layer may include titanium tungsten.

The method may include forming a backmetal layer on a side of the semiconductor substrate opposing the side where the interconnect may be located.

Implementations of a semiconductor device may include an interconnect that may include a tantalum layer directly coupled with a first copper layer a titanium tungsten layer directly coupled with the first copper layer; a second copper layer coupled directly with the titanium tungsten layer; and a metal layer directly coupled to the second copper layer. The device may include a gate that may include a tantalum layer directly coupled with a first copper layer; a polyimide layer directly coupled over the first copper layer; a titanium tungsten layer directly coupled over the polyimide layer; a second copper layer coupled directly with the titanium tungsten layer; and a metal layer directly coupled to the second copper layer.

Implementations of a semiconductor device may include one, all, or any of the following:

The device may include a gate feed including a tantalum layer directly coupled with a first copper layer.

The device may include a second polyimide layer formed around the metal layer.

The metal layer may include only silver.

The metal layer may include nickel and a gold layer, a palladium layer, or a silver layer may be directly coupled to the nickel of the metal layer.

The layer of polyimide may extend over the gate feed.

The second layer of polyimide may extend over the gate feed.

The tantalum layer may be directly coupled over a metallization layer of a semiconductor substrate and the semiconductor substrate may include a backmetal layer formed thereon.

Implementations of a method of preventing contamination may include processing a semiconductor substrate to a final metallization layer in a first fabrication location; forming a barrier layer over the final metallization layer in the first fabrication location; placing the semiconductor substrate in a transporter; and moving the transporter to a second fabrication location separate from the first fabrication location for formation of one or more layers that include copper. The method may include never allowing the transporter to return to the first fabrication location.

Implementations of a method of preventing contamination may include one, all, or any of the following:

Never allowing the transporter to return to the first fabrication location further may include providing a visual barrier to transport of the transporter back into the first fabrication location.

Never allowing the transporter to return to the first fabrication location further may include providing a physical barrier to transport of the transporter back into the first fabrication location.

Never allowing the transporter to return to the first fabrication location further may include where the second fabrication location may be in a different building than the first fabrication location.

The barrier layer may include one of tantalum, tantalum nitride, titanium, titanium nitride, titanium tungsten, titanium tungsten nitride, or any combination thereof.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a side cross sectional view of an implementation of a semiconductor substrate with pads formed thereon;

FIG. 2 is a side cross sectional view of the implementation of the semiconductor substrate of FIG. 1 following deposition of a seed layer;

FIG. 3 is a side cross sectional view of the implementation of the semiconductor substrate of FIG. 2 following formation of a photoresist pattern thereon;

FIG. 4 is a side cross sectional view of the implementation of the semiconductor substrate of FIG. 3 following electroplating of copper pads thereon;

FIG. 5 is a side cross sectional view of the implementation of the semiconductor substrate of FIG. 4 following formation of one or more layers over the exposed surface of the copper pad and removal of the photoresist;

FIG. 6 is a side cross sectional view of the implementation of the semiconductor substrate of FIG. 5 following etching/removal of the seed layer;

FIG. 7 is a side cross sectional view of the implementation of the semiconductor substrate of FIG. 6 following formation of a patterned polyimide layer over the copper pads;

FIG. 8 is a side cross sectional view of the implementation of the semiconductor substrate of FIG. 7 after formation of an additional layer on the exposed portion of the copper pad;

FIG. 9 is a side cross sectional view of another implementation of a semiconductor substrate with pads formed thereon;

FIG. 10 is a side cross sectional view of the implementation of the semiconductor substrate of FIG. 9 with a seed layer formed thereon;

FIG. 11 is a side cross sectional view of the implementation of the semiconductor substrate of FIG. 10 following formation of a photoresist pattern thereon;

FIG. 12 is a side cross sectional view of the implementation of the semiconductor substrate of FIG. 11 following electroplating of copper pads thereon;

FIG. 13 is a side cross sectional view of the implementation of the semiconductor substrate of FIG. 12 following removal of the photoresist and application of a layer to the top surfaces of the copper pads;

FIG. 14 is a side cross sectional view of the implementation of the semiconductor substrate of FIG. 13 following removal of the seed layer;

FIG. 15 is a side cross sectional view of the implementation of the semiconductor substrate of FIG. 14 following formation of a patterned polyimide layer over the copper pads and etching/removal of the layer over the top surface of the copper pad;

FIG. 16 is a side cross sectional view of the implementation of the semiconductor substrate of FIG. 13 following formation of a patterned polyimide layer over the copper pads;

FIG. 17 is a side cross sectional view of the implementation of the semiconductor substrate of FIG. 12 following removal of the photoresist layer and seed layer;

FIG. 18 is a side cross sectional view of the implementation of the semiconductor substrate of FIG. 17 following formation of a patterned polyimide layer over the copper pads;

FIG. 19 is a side cross sectional view of the implementation of the semiconductor substrate of FIG. 18 following formation of a metal layer over the exposed portion of the copper pad; and

FIG. 20 is a side cross sectional view of an implementation of a semiconductor substrate with a barrier layer and a first seed layer formed thereon;

FIG. 21 is a side cross sectional view of the semiconductor substrate of FIG. 20 following application of a photoresist layer thereon;

FIG. 22 is a side cross sectional view of the semiconductor substrate of FIG. 21 following formation of a pattern with the photoresist layer that contains a plurality of openings thereon;

FIG. 23 is a side cross sectional view of the semiconductor substrate of FIG. 22 following electroplating of a first copper layer in the plurality of openings;

FIG. 24 is a side cross sectional view of the semiconductor substrate of FIG. 23 following removal of the patterned photoresist layer;

FIG. 25 is a side cross sectional view of the semiconductor substrate of FIG. 24 following etching of the barrier layer and the first seed layer;

FIG. 26 is a side cross sectional view of the semiconductor substrate of FIG. 25 following application of a polyimide layer thereon;

FIG. 27 is a side cross sectional view of the semiconductor substrate of FIG. 26 following patterning of the polyimide layer;

FIG. 28 is a side cross sectional view of the semiconductor substrate of FIG. 27 following formation of a second seed layer over the polyimide layer;

FIG. 29 is a side cross sectional view of the semiconductor substrate of FIG. 28 following formation of a patterned photo resist on the second seed layer;

FIG. 30 is a side cross sectional view of the semiconductor substrate of FIG. 29 following forming a second copper layer and a metal layer via electroplating;

FIG. 31 is a side cross sectional view of the semiconductor substrate of FIG. 30 following removal of the patterned photoresist layer;

FIG. 32 is a side cross sectional view of the semiconductor substrate of FIG. 31 following etching of the second seed layer;

FIG. 33 is a side cross sectional view of the semiconductor substrate of FIG. 32 following application of a second polyimide layer thereon;

FIG. 34 is a side cross sectional view of the semiconductor substrate of FIG. 33 following patterning of the second polyimide layer;

FIG. 35 is a side cross sectional view of an implementation of a semiconductor substrate with copper pads and a metal layer of only electroplated silver; and

FIG. 36 is a side cross sectional view of another implementation of a semiconductor substrate with copper pads and a metal layer of only electroplated silver where two polyimide layers are employed.

### DESCRIPTION

This disclosure, its aspects and implementations, are not limited to the specific components, assembly procedures or method elements disclosed herein. Many additional components, assembly procedures and/or method elements known in the art consistent with the intended copper pad metallization systems will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such copper pad metallization systems, and implementing components and methods, consistent with the intended operation and methods.

In various semiconductor devices, logic circuits and power circuits can be combined. For example, in the case of a semiconductor device used to operate an automatic window opener in an automobile, the logic portion of the device senses the control signal indicating the window is to be raised or lowered and then activates the power portion (a metal oxide field effect transistor [MOSFET]) to transfer power to the motor for the specified period of time to allow the window to physically be raised or lowered. The voltage and power used by the logic portion of the device is typically much smaller in comparison with the voltage and power needed to operate the motor, so if the electrical interconnects used for the logic portion are used for the power portion of the device, the electrical interconnects can be damaged through overheat and/or excessive current load, even during the relatively short time that the high voltage/amperage is experienced during operation. In such systems, electrical interconnects adapted for higher power operation, such as thick copper interconnects like pads/bumps/pillars greater than 10 microns in height can be used to help the interconnects avoid damage during the high voltage transient load period. Similar structures in the form of metal lines greater than 10 microns in height are also used, and the principles disclosed herein can also be applied with metal lines. As wirebonding is often used to connect the source and drain pads of the MOSFET, for example, the ability to create reliable wirebonds with a wire bondable material of the thick copper interconnects is a design consideration when such combined logic and power circuits are combined in a semiconductor device.

In some process implementations, thick copper pads with a layer of gold and/or nickel on their upper surface are used. Since the sidewalls of the thick copper pads remain exposed in this process, the likelihood that particulate contamination can cause shorting between pads is increased as there is nothing present to fill the gaps between adjacent pads. In other process implementations, to assist with reducing the likelihood that particulate contamination can cause failures with the thick copper pads, the use of polyimide layers that fill in the space between the pads and cover the upper surface of the thick copper pillars is used in applications such as, by non-limiting example, automotive and other vehicle industries. Openings in the polyimide layer to expose the upper portion of the thick copper pillars are made into which the wirebonds are formed. In order to get the polyimide to adhere to the gold on the upper surface of the thick copper pads however, a film of palladium needs to be used as the top layer over the upper surface. The polyimide can also adhere to a layer of aluminum formed at the top layer over the upper surface of the thick copper pads, but does not adhere to the gold of the thick copper pads themselves.

Various methods for forming thick copper interconnect systems are disclosed in this document that utilize various layers of materials to which a polyimide material will adhere over the top surface of a thick copper pad/bump/pillar. These methods are merely exemplary, and combinations of these methods and materials disclosed herein may be employed in various system and method implementations. While in this document the term “pads” is used primarily to describe the methods and structures herein, it should be understood that the same principles may be applied with other metallization structures including bond pads, metal lines, or other large areas of metallization like dummy structures used to ensure local and wafer-level uniformity.

One of the challenges of forming wirebonds with pure copper pads is that the presence of copper oxide on the bond surface of the pads interferes with the formation of the intermetallic and alloy compounds that form a good mechanical and electrical connection between the bond wire and the copper pads. Thus, the ability to minimize and reduce the formation of copper oxide during the processing steps assists with the creation of good wirebonds. The various methods implementations disclosed herein show various approaches to reduce copper oxide formation on the bond surface/top surface of the copper pads disclosed herein.

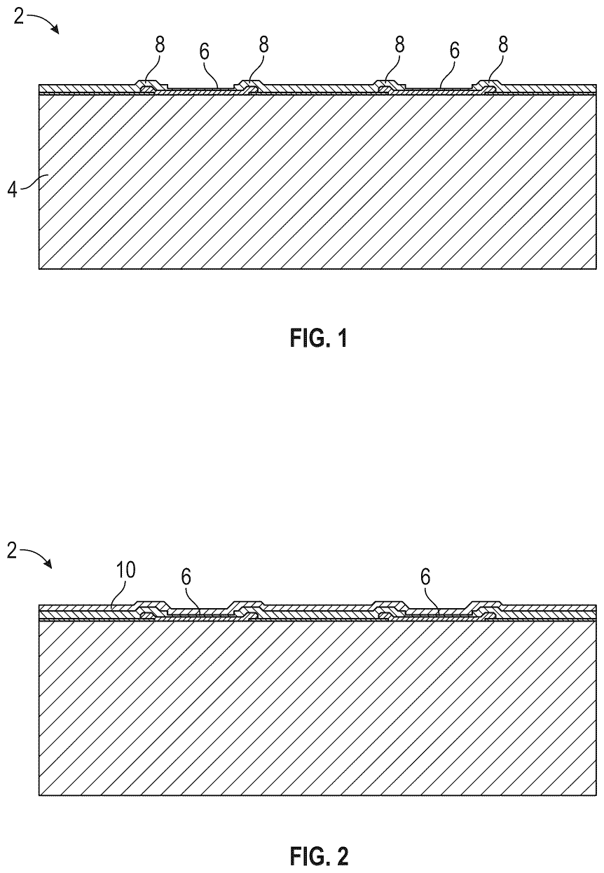

Referring to FIG. 1, a side cross sectional view of a semiconductor device 2 is illustrated which includes semiconductor substrate portion 4 on which is formed a plurality of pads 6. These pads 6 represent the outer layer of a stack of materials that are formed on/in the semiconductor substrate portion 4 which, for the sake of easier illustration, are not shown in FIG. 1 or the other figures, but are understood to be present as forming the active device(s) included in the semiconductor device 2. This stack of material helps forms structures such as, by non-limiting example, transistors, diodes, interconnects, traces, vias, insulating layers, and any other component of an active semiconductor device. Around each of the pads 6 is a layer of passivation material 8 which may be, by non-limiting example, silicon nitride, a polyimide, or another electrically insulating material. The particular material of the semiconductor substrate may be, by non-limiting example, silicon, silicon carbide, silicon on insulator, ruby, sapphire, gallium arsenide, gallium nitride, or any other semiconductor material type. The particular types of semiconductor devices that may employ the method implementations disclosed here may include, by non-limiting example, transistors, MOSFETs, insulated gate bipolar transistors (IGBTs), diodes, power devices, high electron mobility transistors (HEMTs), rectifiers, or any other power semiconductor device or other active semiconductor device type. While in FIG. 2 just two pads are illustrated, it is understood that this is merely for illustration convenience as the method implementations disclosed may be employed at the die-level or wafer-level portions of the fabrication process and many more pads than just two pads may be employed in various implementations.

Referring to FIG. 2, a side cross sectional view of the semiconductor device 2 of FIG. 1 is illustrated following formation of a seed layer 10 thereon for use in electroplating. The use of the seed layer 10 permits the formation of an electrical connection to the seed layer material covering each of the pads 6 during the electroplating operation. In various implementations, the seed layer 10 may be formed by sputtering. The seed layer 10 may include, by non-limiting example, a titanium and tungsten film, a copper film, any combination thereof, or another metal film type that permits electroplating of pure copper to the seed layer.

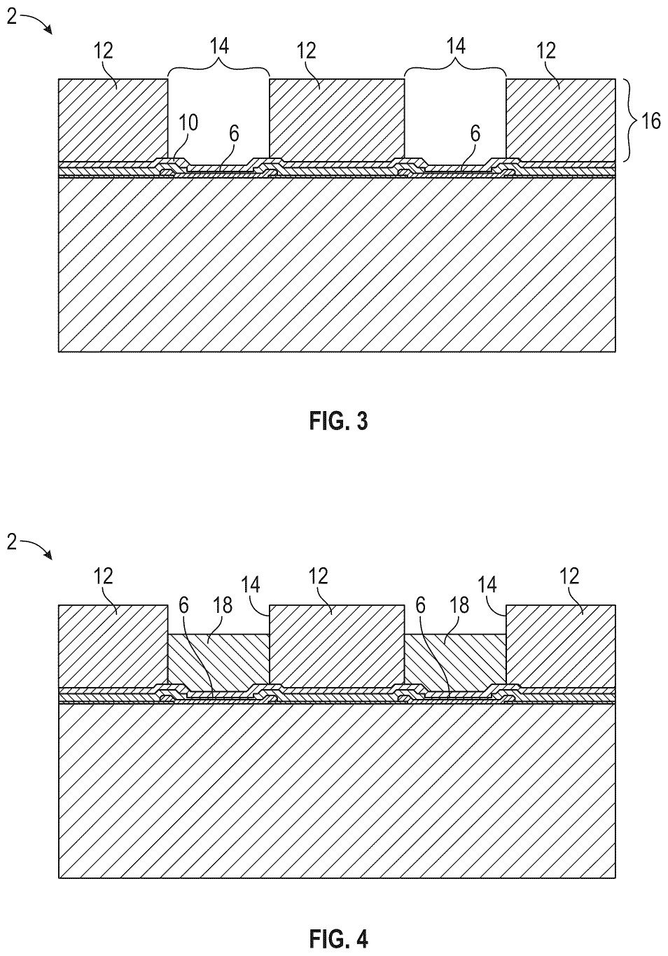

Following formation of the seed layer 10, referring to FIG. 3, a layer of photoresist 12 is applied which is then patterned. The application process for the photoresist 12 may include, by non-limiting example, spin coating, dispensing, stencil printing, squeegee application, or any other method for forming a uniform layer of material above the seed layer 10. The patterning process used may be specific to the particular type of photoresist employed. For example, where a positive photoresist is employed, the regions of the photoresist above the pads 6 are exposed with an electromagnetic radiation source through a mask to cause a corresponding reaction in the material of the photoresist that permits a developing solution to wash away the exposed regions. Where a negative photoresist is employed, the regions of the photoresist outside the pads are exposed to electromagnetic radiation causing a corresponding reaction in the material of the photoresist that prevents the developing solution from washing away the exposed regions. As illustrated in FIG. 3, the openings 14 in the photoresist 12 are larger than the size of the pads to allow the passivation material and any other under bump materials to assist in supporting the to-be-formed bump and help prevent issues like bump cracking later during operation. However, in other implementations, the size of the openings 14 may be the same as or substantially the same as the size of the pads. The height/thickness 16 of the photoresist 12 is set to be higher than or substantially the same as the height of the copper pads to be electroplated to help form the sidewalls and a flat upper/bonding surface for each of the copper pads.

Referring to FIG. 4, the semiconductor device 2 is illustrated following completion of the electroplating process that forms a copper pad/bump/pillar 18 within each of the openings 14 of the photoresist 12 which is mechanically and electrically connected with each corresponding pad 6. In this implementation, a pure copper pad has been formed, meaning that substantially all of the material of the pad is formed of just copper. In other implementations, however, a copper alloy could be electroplated, depending on the electrical or mechanical characteristics desired for the pads.

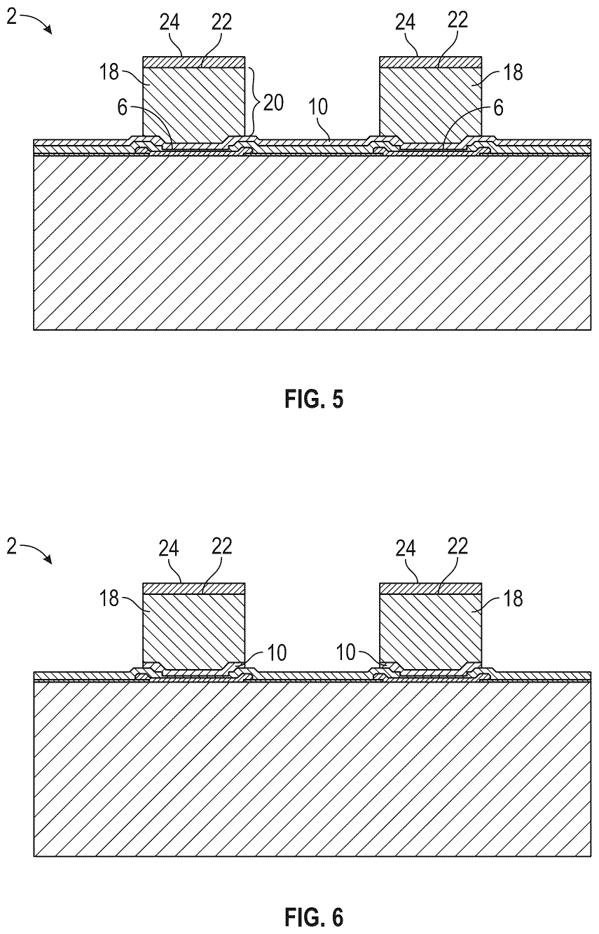

Referring to FIG. 5, the semiconductor device is illustrated following formation of one or more layers of material 24 on the top side/bonding surface 22 of each of the copper bumps 18 and after stripping/removal of the photoresist. In various method implementations, the one or more layers may be formed using electroless plating. Where the one or more layers are formed using electroless plating, the electroless plating may be carried out while the photoresist is still present around the copper pads 18 as illustrated in FIG. 4 after electroplating of the copper pads. In other implementations however, the electroless plating may take place after the photoresist has been removed and after removal of the seed layer 10 as in the structure illustrated in FIG. 6. While the one or more layers 24 are illustrated as being present on only the top of the copper pads 18 in FIG. 5 for ease of illustration, where the electroless plating takes place after removal of the photoresist and seed layer, it is understood that the material of the one or more layers may deposit on all exposed surface of each of the copper pads 18. Thus, if the one or more layers 24 are desired to be formed only on the bonding surface 22 of the copper pads 18, then the electroless plating would take place while the photoresist 12 is still in place as illustrated in FIG. 4.

While the previous discussion discloses the use of electroless plating to form the one or more layers of material 24, in other method implementations, sputtering may be used to form the one or more layers of material 24. In such implementations, the sputtering takes place following the electroplating of the copper pads 18 while the photoresist 12 is still in place around the pads as illustrated in FIG. 14. The photoresist 12 is then stripped/removed as previously described, leaving the one or more layer of material 24 on the bond surface 22 of each of the copper pads 18 as illustrated in FIG. 5.

The materials used in the one or more layers of material 24 depend on the particular method of formation. Where electroless plating is employed, the material of the one or more layers may be nickel, gold, or palladium as a single layer in some implementations. In others, the material of the one or more layers may be nickel, gold, or palladium in two or more separate layers each formed through electroless plating. In yet other implementations, the material of the one or more layers may be any combination of nickel, gold, and/or palladium formed in a single layer or in multiple layers using electroless plating. Where the use of sputtering is employed, the material of the one or more layers may be, by non-limiting example, either titanium, nickel, and gold or titanium, nickel, and palladium formed in either a single layer or as separate layers.

The process of removing the photoresist may take place using various methods, including, by non-limiting example, solvent stripping, washing, ashing, etching, or any other method for removing polymer material. As illustrated, the as-plated copper pads 18 are then exposed and rise above the surface of the seed layer 10 at a desired height/thickness 20. As the seed layer 10 electrically shorts all of the copper pads 18 and all of the pads 6 together, it needs to be removed to electrically isolate all of the pads 6 from each other once again.

Referring to FIG. 6, the semiconductor device 2 of FIG. 5 is illustrated following removal of the seed layer material 10 from around the copper pads 18, leaving the seed layer 10 present only as an under bump material of each of the copper pads. The removal of the seed layer 10 may be carried out using etching in various method implementations. FIG. 6 also illustrates that, after the seed layer 10 has been removed, the one or more layers of material 24 remain formed onto the top surface/bonding surface 22 of each of the copper pads 18. In various implementations, the one or more layers of material 24 may be formed of a material that is not removed/etched by the process used to remove/etch the seed layer.

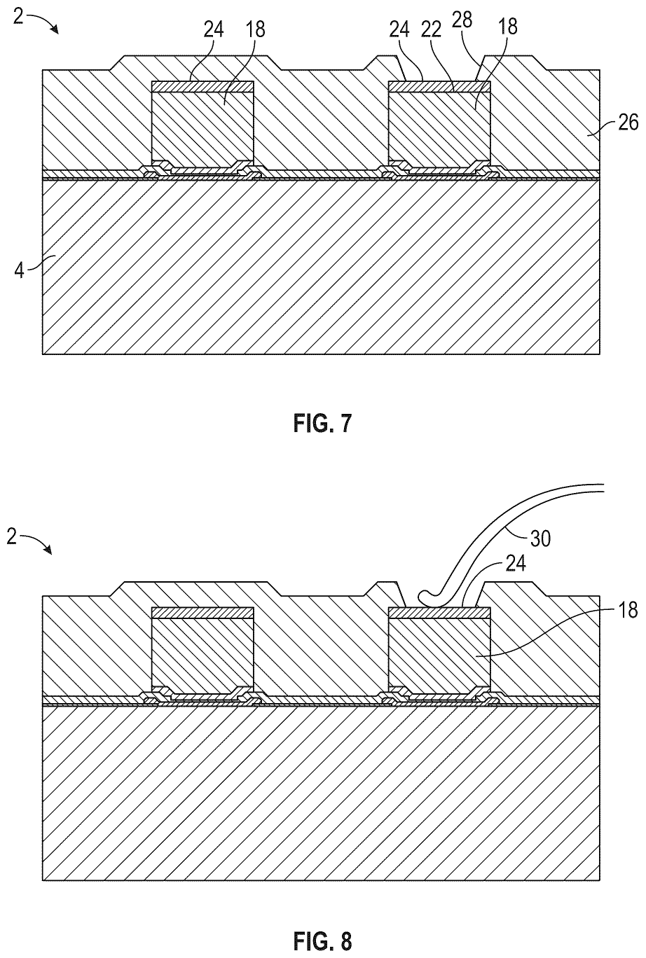

Referring to FIG. 7, the semiconductor device 2 is illustrated following application of a layer of polyimide 26 over the copper pads 18 and the patterning of opening 28 over the top surface/bonding surface 22. Note that not every copper pad 18 may have the top surface 22 with the one or more layers of material 24 exposed through an opening in the layer of polyimide 26. This may be because not all of the pads 6 are actually used for electrical interconnects and may be dummy pads used to preserve a certain amount of metal density at the pad layer to help improve processing uniformity or to help provide mechanical support/strength to the semiconductor device. The particular patterning method and process used to form the opening 28 in the polyimide 26 depends on the material of the polyimide and whether it is patterned photolithographically using positive or negative exposure processes like those previously described in this document. Because material types used in the one or more layers of material 24 are those previously described in this document, the polyimide 26 will adhere to the one or more layers 24 to form the opening 28 and allow for wirebonding into the opening 28. FIG. 8 illustrates the semiconductor device 2 following wire bonding of a bond wire 30 onto the one or more materials 24 and to the copper pad 18.

Prior to the wirebonding process, the semiconductor device 2 may have the semiconductor substrate portion thinned through, by non-limiting example, backgrinding, lapping, separating, polishing, or any other thinning process. Because of the use of the polyimide 26, the mechanical strength of the remaining portion of the semiconductor substrate portion may be improved to support a thinner die than could otherwise be produced without the presence of the polyimide 26 in the material stack. A wide variety of method variations may be constructed using the principles disclosed in this document.

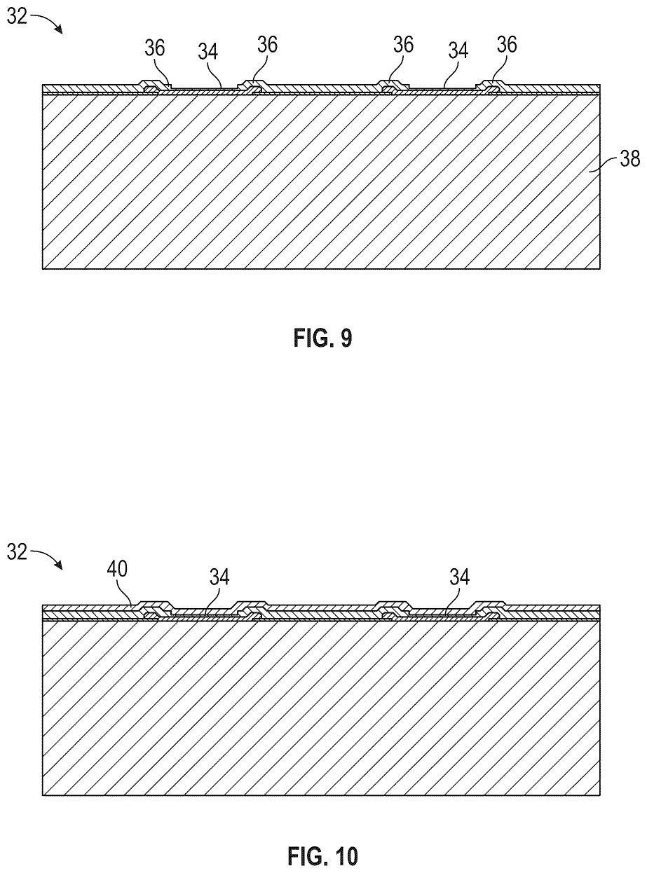

Referring to FIG. 9, a second semiconductor device 32 is illustrated in a side cross sectional view that is similar in structure to the semiconductor device 2 of FIG. 1. The semiconductor device 32 includes pads 34 which are surrounded by passivation material 36. In the various method implementations, the material of the semiconductor substrate portion 38 of the semiconductor device 32 may be any disclosed in this document. In the various method implementations, the material of the passivation material 36 may also be any disclosed in this document. Also, the semiconductor device 32 may be any semiconductor device type disclosed in this document.

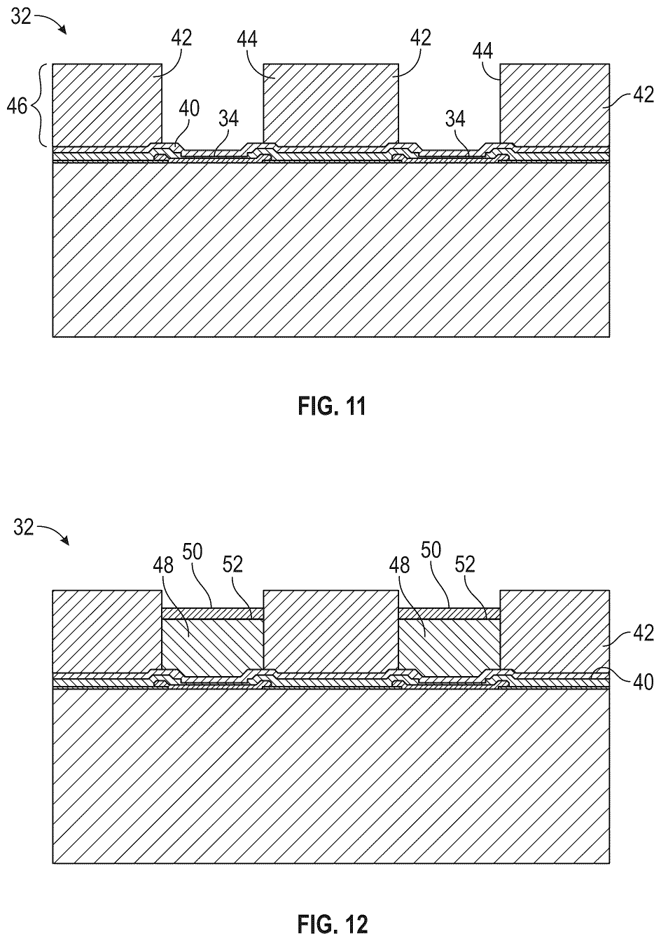

Referring to FIG. 10, the semiconductor device 32 is illustrated in a side cross sectional view following formation of a seed layer 40 over the pads 34. The material of the seed layer 40 may be any disclosed in this document used for seed layers for electroplating copper. FIG. 11 illustrates the semiconductor device 32 following formation of a patterned layer of photoresist 42 over the seed layer 40 with openings 44 over the pads 34. The material of the photoresist 42 may be any disclosed in this document and may be patterned using any of the patterning method implementations disclosed herein in various method implementations. The height/thickness 46 of the photoresist 42 above the seed layer 40 is again set at a level to achieve/support formation of copper pads at a desired thickness during electroplating.

Referring to FIG. 12, the semiconductor device 32 is illustrated in a side cross sectional view following electroplating of copper pads 48. The electroplating process for forming the copper pads 48 and the material of the copper pads 48 may be any disclosed in this document. FIG. 12 also illustrates the semiconductor device 32 following the formation of one or more layers 50 over the top surface/bonding surface 52 of each of the copper pads 48. In various method implementations, the one or more layers 50 may include different materials formed and processed using corresponding methods. In a particular implementation, the one or more layers 50 is an organic coating that, when applied, prevents or substantially prevents reaction of oxygen with the newly plated copper of the copper pads 48, thus reducing the formation of copper oxide on the bonding surface 52. This organic coating is applied soon after the completion of the electroplating of the copper pads, thus helping to seal the bonding surface 52 of the copper pads 48 from reacting further with oxygen. Furthermore, the organic coating is a material to which a subsequently applied polyimide material will adhere. Also, the organic material in this implementation is one that a wirebond can be formed through during the wirebonding process and does not involve a cleaning or removal step.

In another implementation, the one or more layers 50 is an organic material that is thicker or more tightly bonded to the copper layer than the previously disclosed organic material of the previous method implementation. This organic material has the same ability to prevent further formation of copper oxide on the bonding surface 52 of the copper bumps 48, but needs to be removed/cleaned from the bonding surface 52 prior to the actual wirebonding using a cleaning step that will be discussed hereafter. In various implementations, the organic materials that may be employed in either method implementations may be organic solderability preservatives marketed by RBP Chemical Technology Inc. of Milwaukee, WI; MacDermid Alpha Electronics Solutions of Waterbury, CT; or Shikoku Chemicals Corporation of Marugame, Kagawa, Japan.

In another implementation, the one or more layers 50 is a layer of aluminum that is deposited on the bonding surface 52 that reacts with oxygen immediately to form aluminum oxide (alumina). In particular implementations, the layer of alumina is deposited using atomic layer deposition and may be between 1 to 5 atoms thick. In other implementations, however, other materials other aluminum may be used in the one or more layer 50, such as, by non-limiting example, titanium nitride, tantalum nitride, any combination thereof, or other material capable of being deposited using ALD. Such a layer is sufficiently thick to prevent diffusion of oxygen to the copper pad 48 and the formation of copper oxide but thin enough to be wire bonded through during the wirebonding process. In various method implementations where atomic layer deposition is employed, the aluminum is deposited while the photoresist 42 is present in the atomic layer deposition chamber leading to the structure illustrated in FIG. 12. In other implementations, however, the aluminum may be deposited after the photoresist 42 has been stripped from the seed layer 40 but before the seed layer 40 is etched. This may take place to avoid issues with outgassing or contamination of the process from the large thickness of photoresist present after the electroplating process has been completed. The aluminum adds the additional benefit in that a subsequently applied polyimide will adhere to the aluminum layer.

In other method implementations, a layer of aluminum between about 1 to about 4 microns is sputtered to form the one or more layers 50. In some implementations, the layer of aluminum may be about 2 microns thick. The layer of aluminum, when applied soon after plating of the copper, may assist with reducing copper oxide formation and also assist with adhesion of the polyimide subsequently formed over the copper pads.

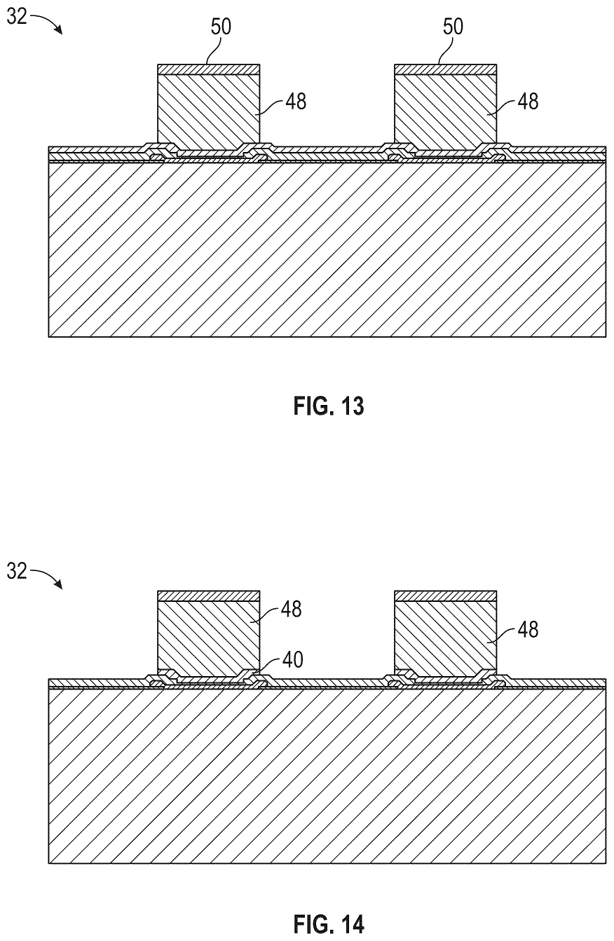

Referring to FIG. 13, the semiconductor device 32 is illustrated in a side cross sectional view following removal of the photoresist. In the various method implementations, the photoresist may be removed using any of the methods disclosed in this document. In FIG. 13, the one or more layers 50 illustrated of the copper pads 48 may be either of the organic materials previously mentioned or the layer of aluminum deposited using atomic layer deposition previously discussed. FIG. 14 illustrates the semiconductor device 32 following removal of exposed portions of the seed layer 40 that are not part of the copper pads 48. The removal of the seed layer 40 may take place using any of the methods disclosed herein. In various methods, the particular removal method may also take into account the resistance of the material present of the one or more layers 50 to the particular removal method. In some implementations where the aluminum layer is present which was applied after removal of the photoresist, causing the aluminum to be deposited on the seed layer 40, a removal method that is capable of removing the aluminum either separately initially or in combination with the material of the seed layer 40 may be employed.

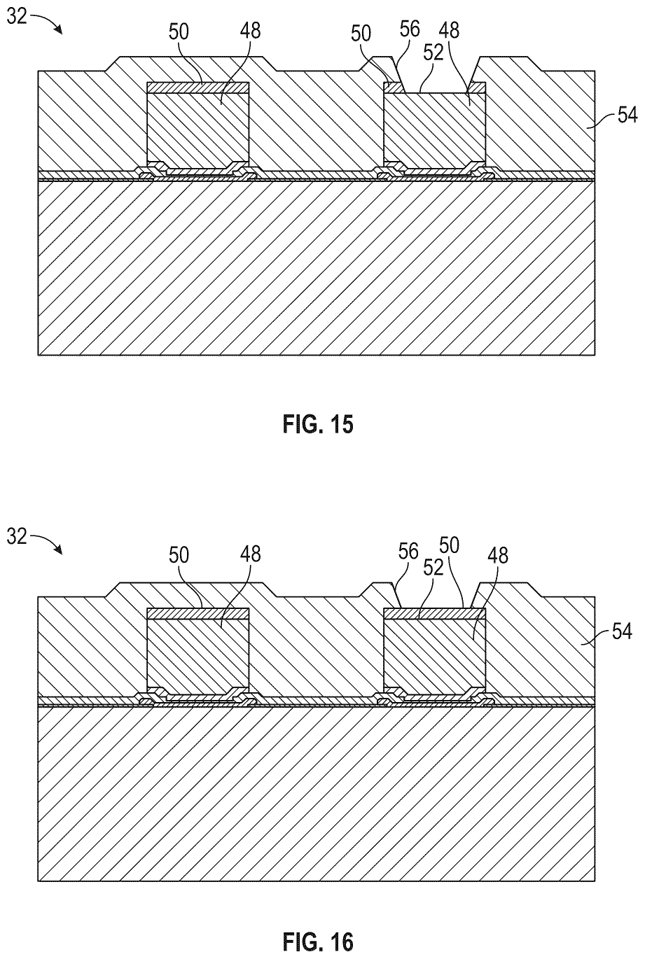

Referring to FIG. 15, the semiconductor substrate 32 is illustrated following application of a polyimide layer 54 over the copper pads 48 and patterning of that layer to form opening 56. FIG. 15 is a side cross sectional view following removal of the material of the one or more layers 50 that exposed through the opening 56. In this method implementation, the material of the one or more layers 50 is the organic material that needs to be removed/cleaned from the bonding surface 52 of the copper pads 48 prior to wirebonding. In this method implementation, because the organic material cannot be bonded through, it needs to be removed following the formation of the polyimide layer 54 while still providing adhesion to the bonding surface 52 of the copper pads 48 for the polyimide.

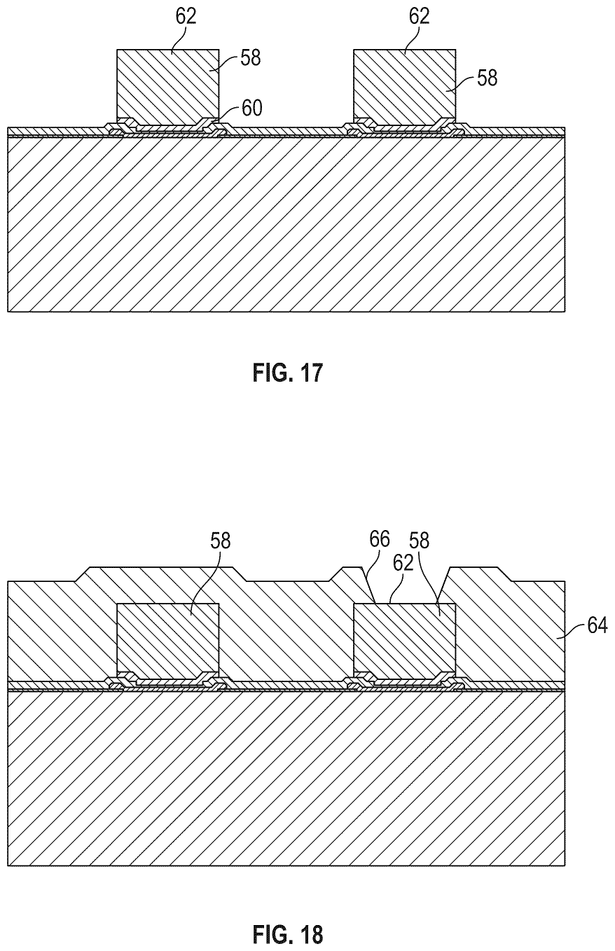

FIG. 16 illustrates an alternative structure that results from an alternative method implementation used where the aluminum layer or the organic coating forms the one or more layers 50 formed over the bonding surface 52. As in FIG. 15, a polyimide layer 54 has been formed over the copper pads 48 and patterned using any of the methods disclosed herein to form opening 56. However, the exposed material of the one or more layers 50 is not removed in this method implementation and so wire bonding takes place by bonding through either the organic coating or the aluminum layer formed by atomic layer deposition. In this way, the bond is not affected by copper oxide while a pure copper pad is still being bonded to while the polyimide layer 54 is still able to adhere to the bonding surface 52 of each of the copper pads 48.

Referring to FIG. 17, copper pads 58 are illustrated after removal of the photoresist as illustrated in FIG. 12 and after etching of the seed layer 60. In this method implementation, however, no layer is applied over the top/bonding surface 62 of the copper pads following formation and prior to etching of the seed layer 60, leaving the top/bonding surface 62 as copper. FIG. 18 illustrates the copper pads 58 of FIG. 17 following formation of a polyimide layer 64 and formation of opening 66 to expose the top/bonding surface 62. In some method implementations, the polyimide layer 64 sufficiently sticks/bonds with the top/bonding surface 62 of the copper pads 58 so that no additional layer is applied to the top/bonding surface 62. In such implementations, the bonding is then carried out directly onto the top/bonding surface 62.

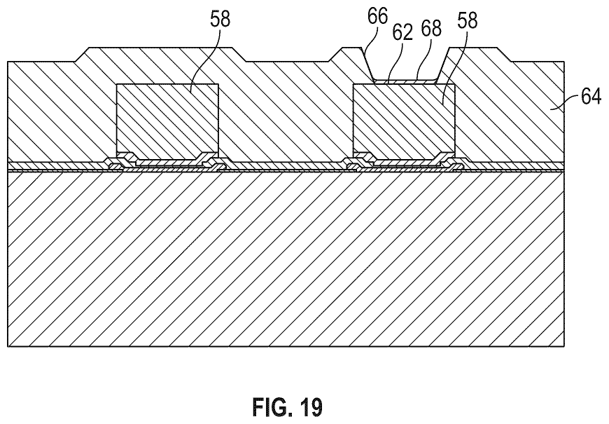

In other method implementations, like the one illustrated in FIG. 19, following forming the opening 66 in the polyimide 64, one or more layers 68 is formed over the top/bonding surface 62 of the copper pad 58. In some implementations, electroless plating may be used to form a layer of nickel, a layer of palladium, a layer of gold, or any combination thereof to form the one or more layers 68. In other implementations, sputtering may be used to apply titanium and aluminum (either as separate layers or a single layer) to form the one or more layers 68. In other implementations, sputtering may be used to apply titanium tungsten and aluminum (either as separate layers or a single layer) to form the one or more layers 68. In yet other implementations, atomic layer deposition may be employed to form the one or more layers 68 of any of the materials disclosed herein used for atomic layer deposition. As illustrated in FIG. 19, where sputtering is used to form the one or more layers 68, the material of the one or more layers 68 may rise up around the edges of the polyimide layer 64 of the opening 66.

A wide variety of possible combinations of electroless plated/sputtered/atomic layer deposition may be employed to form various layers on the top/bonding layer 62 of the copper pads 58 in various method implementations.

The various method and system and method implementations that follow utilize semiconductor substrates on/in which various semiconductor devices have been formed to a final layer of metallization. By final layer of metallization is meant that the last layer of metallization has been formed just prior to the formation of any pads used to form the actual electrical interconnects with various semiconductor package electrical connector types (bond wires, clips, bumps, pins, at the like). A wide variety of semiconductor substrate types may be employed in the various method and system implementations disclosed herein including, by non-limiting example, silicon carbide, silicon, silicon-on-insulator, gallium nitride, gallium arsenide, ruby, sapphire, wide bandgap materials, or other semiconductor substrate types. The semiconductor devices may be any of a wide variety of device types that employ gate pads or other pads for power or signal including, by non-limiting example, metal oxide field effect transistors (MOSFETs), insulated gate bipolar transistors (IGBTs), high electron mobility transistors (HEMTs), bipolar junction transistors (BJTs), diodes, power semiconductor devices, rectifiers, thyristors, or any other semiconductor device that employs a pad-type interconnect.

In a particular power MOSFET device design, two layers of aluminum silicon copper about 7 microns to about 10 microns thick have been used with the first layer having a thickness of about 3 microns. During temperature cycling reliability testing designed to simulate operation of the power MOSFET over its entire design lifetime, recrystallization of the aluminum silicon copper and corresponding deformation of the first and second layers of aluminum silicon copper has been observed following failure analysis. The deformation has been observed to be so significant that cracking of the passivation layers on the die edge and dielectric layer material cracking in gate runner structures next/under the source pad has been observed. Where an electroless plated nickel palladium gold layer is plated over the first layer of aluminum silicon copper, cracking of the nickel palladium gold layer has also been observed during known good die testing due to softening of the aluminum silicon copper layers caused by heating of the layers which permits recrystallization and corresponding deformation to begin.

Also, where soldering is used to attach to the nickel palladium gold layer, the nickel can become fully consumed in the joint forming process or during subsequent operation of the device which creates a weak joint between the aluminum silicon copper layer and the solder which can result in device failure. Silicon carbide MOSFETs disclosed herein may be operated in harsher application environments that demand higher power dissipation and/or continuous operation at about 185 C to about 200 C. Under these conditions, the degradation of the electroless plated nickel palladium gold in combination with the deformation of the about 5 micron thick first and second layers of aluminum silicon copper for the source pad may cause enough failures during reliability testing indicating that field failure likelihood is unacceptably high.

To combat the deformation of the first and second aluminum silicon copper layers, elimination of the use of aluminum copper layers in favor of electroplated copper layers is disclosed herein. Also, the elimination of electroless plated layers and the use of electroplated layers is also disclosed herein.

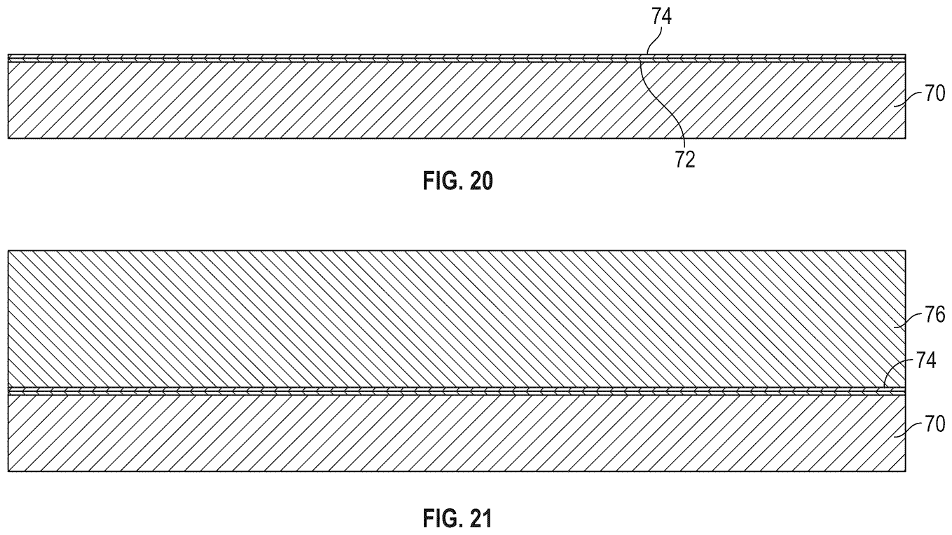

The interconnect implementations disclosed herein are constructed using various implementations of methods of forming interconnects. Referring to FIG. 20, an implementation of a semiconductor substrate 70 is illustrated following formation of a barrier layer 72 and a first seed layer 74 thereon. In the side cross sectional view of FIG. 20, all of the device layers of the semiconductor devices up through the final metallization layer are not shown for the purposes of easier illustration. Thus the barrier layer is formed on the final metallization of the semiconductor devices formed in/on the semiconductor substrate 70. The barrier layer 72 includes tantalum and in some method implementations also includes tantalum nitride. The use of the tantalum or tantalum/tantalum nitride in the barrier layer 72 prevents migration of copper into the die stack and semiconductor substrate during processing and after formation of the interconnects. This may be accomplished because the valence electrons available in the tantalum layer help neutralize migrating copper ions and the nitride in the tantalum nitride helps prevent physical diffusion of the copper ions through the layer. The barrier layer 72 is formed using sputtering in various method implementations. In various method implementations, sputtering of the tantalum proceeds for a predetermined period of time and then nitrogen is introduced into the sputtering chamber to allow for the formation of a certain amount of tantalum nitride for the remaining period of sputtering. Other materials could be used in various barrier layer implementations that are applied with sputtering using a similar nitrogen introduction process including titanium and titanium nitride or titanium tungsten and titanium tungsten nitride. Additional materials that may be employed in the barrier layer may include, by non-limiting example, titanium, titanium tungsten, or tantalum.

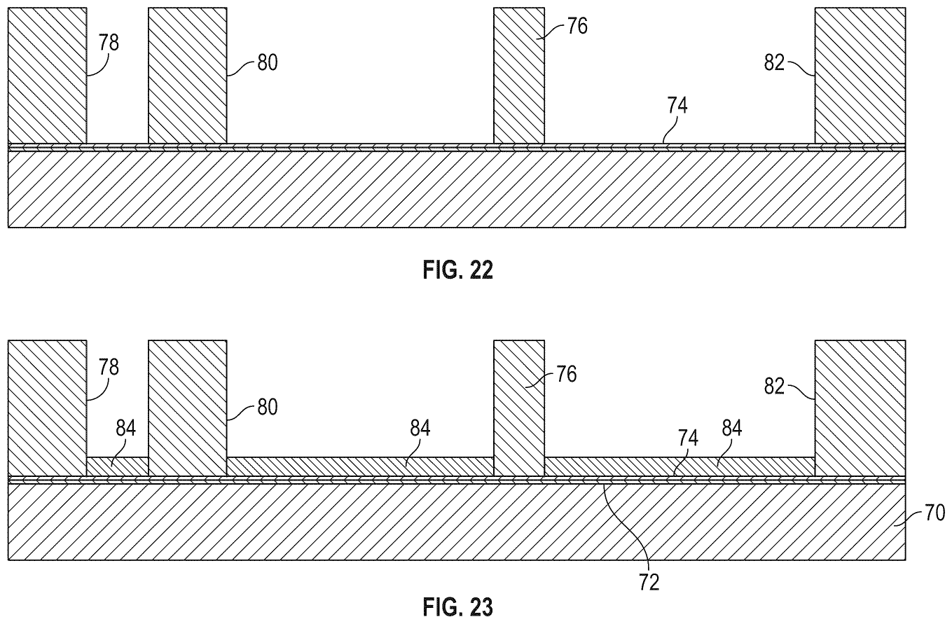

The first seed layer 74 includes copper which may be sputtered over the barrier layer 72 in various method implementations. The seed layer is used to allow for subsequent electrolytic copper deposition. Referring to FIG. 21, a photoresist layer 76 has been applied over the first seed layer 74. The photoresist layer 76 may be spin coated, squeegee printed, stencil printed, or applied in any other method consistent with the material of the photoresist. Following application of the photoresist layer 76, the photoresist is then exposed and developed to form a patterned photoresist layer 76 over the first seed layer 74. FIG. 22 illustrates how the patterned photoresist layer forms a plurality of openings 78, 80, 82 over the first seed layer 74.

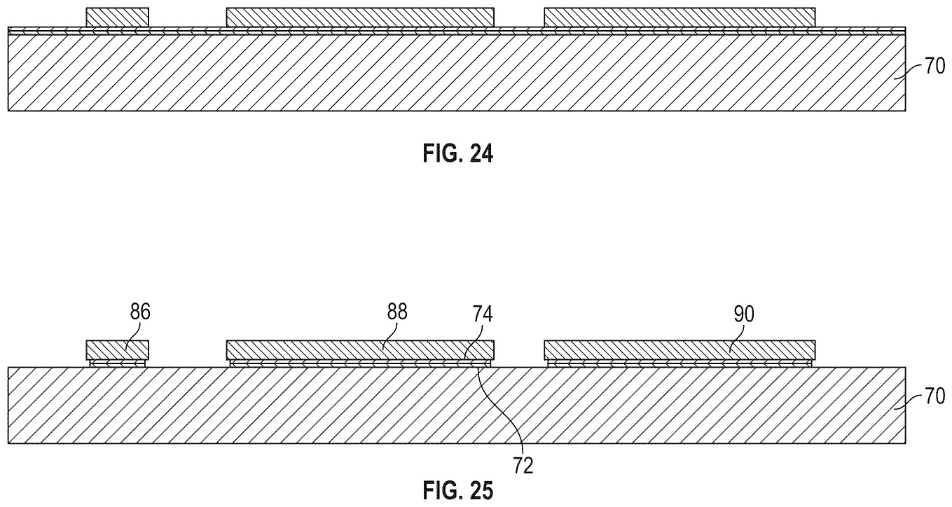

Referring to FIG. 23, the semiconductor substrate 70 is illustrated following electroplating of a first copper layer 84 into the openings 78, 80, 82 of the photoresist layer 76 using the electrical continuity of the seed layer 74/barrier layer 72. The electroplated first copper layer 84 has less ductility than aluminum, aluminum silicon, or aluminum silicon copper and thus provides greater mechanical strength and resistance to deformation under the temperature stresses imposed during high temperature cycling and continuous temperature operation above 185 C. The first copper layer 84 forms a first layer of a copper pad or copper interconnect. In various implementations, the thickness of the copper pad may be between about 2 microns to about 25 microns. In particular implementations, the thickness of the copper pad may be between about 5 microns to about 10 microns. FIG. 24 illustrates the semiconductor substrate 70 following removal of the photoresist layer 76 which may take place using ashing, solvent stripping, or any other removal process consistent with the material of the photoresist layer.

Referring to FIG. 25, the semiconductor substate 70 is illustrated following an etching process that removes the first seed layer 74 and barrier layer 72 from between what is now a gate runner 86, a pad (source pad) 88, and first portion of a gate pad 90. The gate pad 90 needs to include a dielectric layer so it can properly function as a gate. The pad 88 also needs more material to be applied in order to form an interconnect with sufficient strength to withstand wirebonding or other bonding forces or to provide a desired electrical characteristic. (desired RDSon, for example).

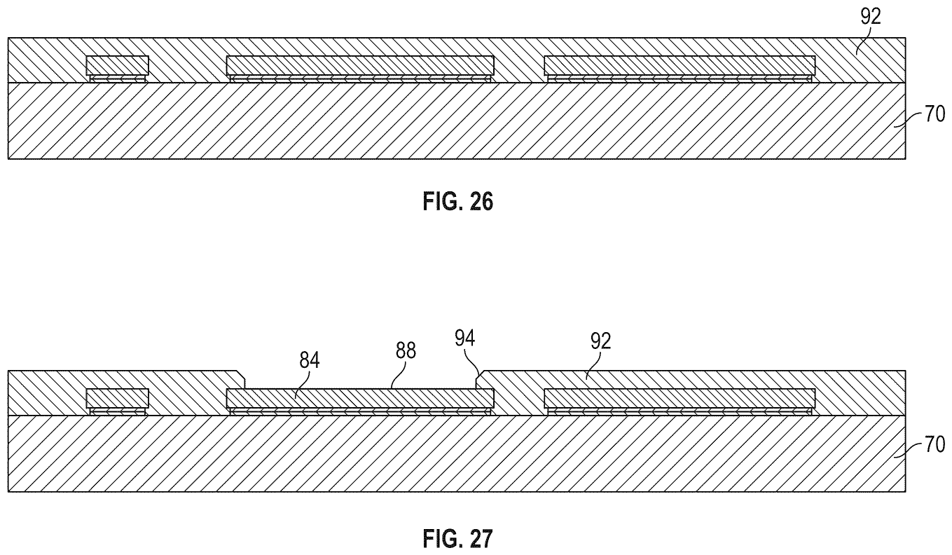

FIG. 26 illustrated the semiconductor substrate 70 following application of a layer of polyimide 92 thereon. In this implementation, the layer of polyimide is applied using spin coating, but other methods consistent with the particular polyimide material may be used including any disclosed this document for applying a photoresist. While the use of a polyimide material disclosed in this method implementation, in other implementations other passivation materials may be used such as silicon dioxide or silicon nitride. Where a hard passivation material is utilized instead of a photodefinable one, then the method includes corresponding lithography processes used to form openings over the pads with corresponding etching operations. The use of a polyimide material results in a layer that is more compliant than a hard passivation material which may be advantageous during subsequent bonding operations or bump/pillar forming operations after the interconnect pad is completed.

Referring to FIG. 27, the semiconductor substrate 70 is illustrated following an exposure and developing operation that forms opening 94 in the polyimide layer 92 over pad 88, exposing the surface of the first copper layer 84. Note that the gate runner 86 remains covered by the polyimide layer 92 to passivate it as no further processing is needed for it in this method implementation. Also, the polyimide layer 92 remains in place over the gate pad 90 (lower gate pad) as the polyimide material itself becomes the dielectric for the finished gate pad. Note that during the application and patterning of the polyimide layer 92, the openings 94 and the dielectric material for the gate pad 90 are formed simultaneously. In various method implementations, the polyimide material for the polyimide layer 92 is selected to have a sufficient/desired dielectric constant to permit the finished gate pad to have the desired electrical characteristics needed to operate. The total thickness of the polyimide layer 92 may be set by the needed thickness of the polyimide above the gate pad 90 in various method implementations.

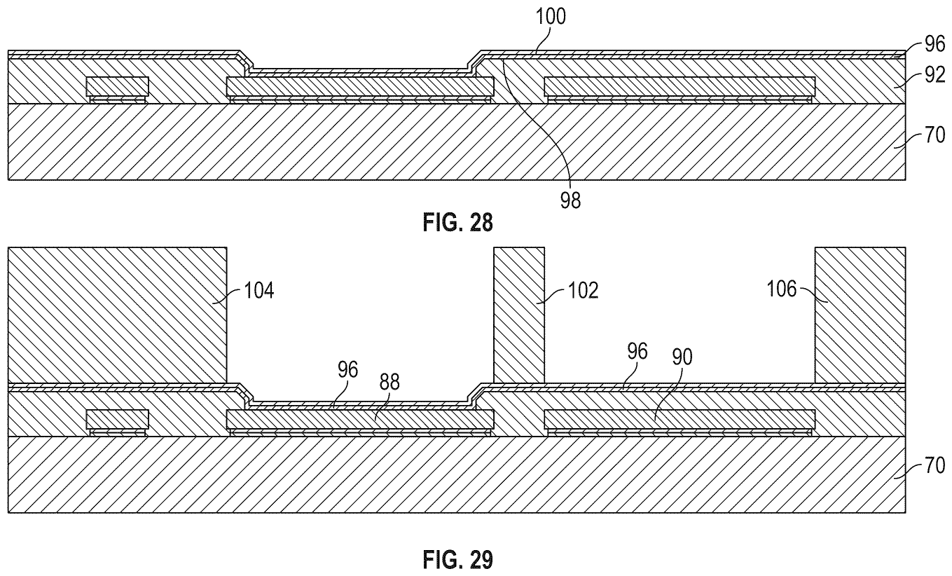

Following the patterning of the photoresist layer 92, a second seed layer 96 is formed over the polyimide layer 92. Various materials and one or more layers may be included in implementations of the second seed layer 96 in various method implementations. In the implementation illustrated in FIG. 28, the second seed layer 96 is composed of two layers, a first layer of titanium tungsten 98 and a second layer of copper 100. In this method implementations, both layers are formed using sputtering. The material(s) of the second seed layer 96 are selected to ensure that they adhere adequately to the surface of the polyimide layer 92 so that electrical continuity across the semiconductor substrate 70 can be maintained during subsequent electroplating operations.

Following formation of the second seed layer 96, the semiconductor substrate 70 is ready for additional processing to permit additional electroplating. Referring to FIG. 29, the semiconductor substrate 70 is illustrated after formation of a second patterned layer of photoresist 102 that includes openings 104, 106 therein that are aligned over the pad 88 and the gate pad 90. The openings 104, 106 expose the second seed layer 96.

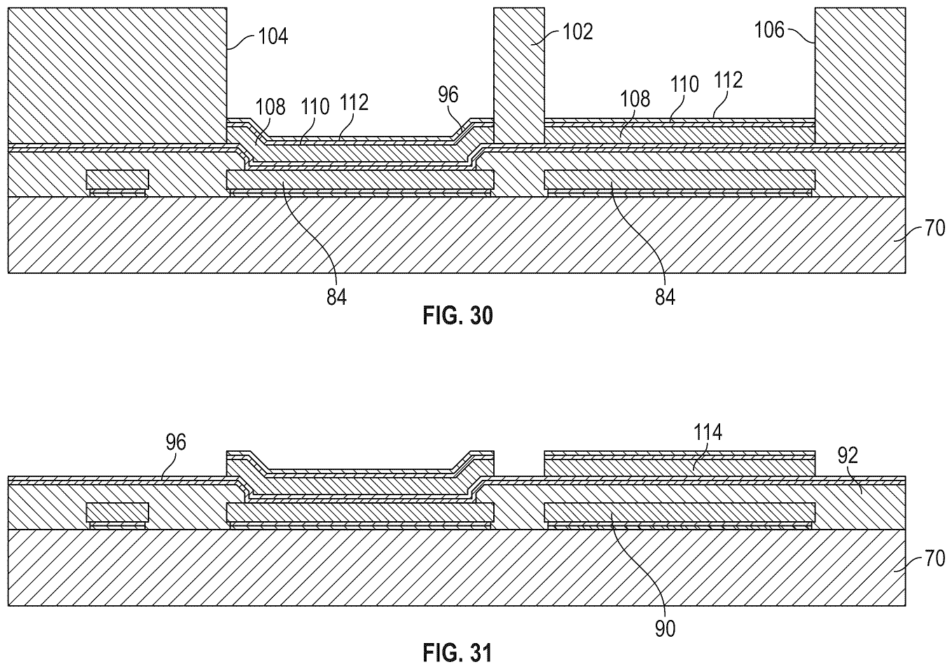

Referring to FIG. 30, the semiconductor substate 70 is illustrated following an electroplating operation into the openings 104, 106 that forms a second copper layer 108 over the seed layer 96. The particular thickness of the second copper layer 108 is designed to establish a full thickness of the copper interconnect as the thickness of the seed layer 96 may be relatively small compared to the total thickness of the copper. In particular implementations, the combined thickness of the first copper layer 84 and the second copper layer 108 may be between about 3 microns to about 60 microns. In some implementations, the combined thickness may be over 60 microns. Thicknesses over 60 microns can be used to absorb more stresses when planarization processes are used with intermediate interlayer dielectric layers in particular pad/interconnect designs. After electroplating of the second copper layer 108, the method includes forming a metal layer over the copper layer by electroplating one or more metal layers into the plurality of openings 104, 106. In the implementation illustrated in FIG. 30, the metal layer includes a nickel layer 110 and a gold layer 112 that have been sequentially electroplated over the second copper layer 108.

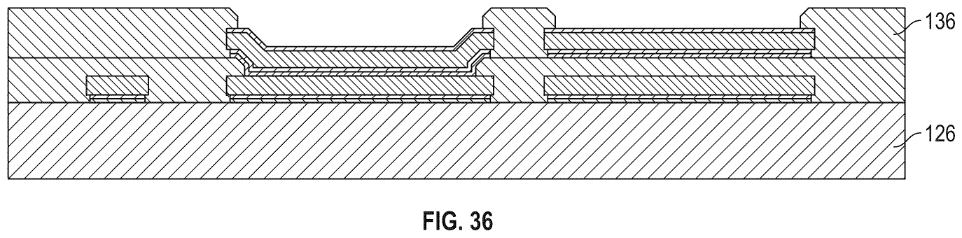

In particular implementations, the nickel layer 110 may have a thickness between about 0.5 microns to about 20 microns. In some implementations, the nickel layer 110 may have a thickness between about 1 micron to about 4 microns. In various implementations a thickness of the gold layer 112 may be between about 0.15 microns to about 1 microns. In particular implementations, the gold layer 112 may have a thickness between 0.25 microns to about 0.5 microns. In various implementations a palladium layer with a thickness between about 0.05 microns to about 0.2 microns may be employed in place of the gold layer 112. The use of the nickel layer may increase the mechanical strength of the interconnect allowing it to better withstand bonding forces exerted during wirebonding. In other method implementations, however, the metal layer is a silver layer directly electroplated over the second copper layer 108. In particular implementations where a silver layer is used, the thickness may be between about 2000 angstroms to about 20,000 angstroms. In particular implementations, the thickness of the silver layer may be between about 4000 angstroms to about 8000 angstroms. Examples of such implementations are found in FIGS. 35 and 36 and will be discussed in more detail hereafter.

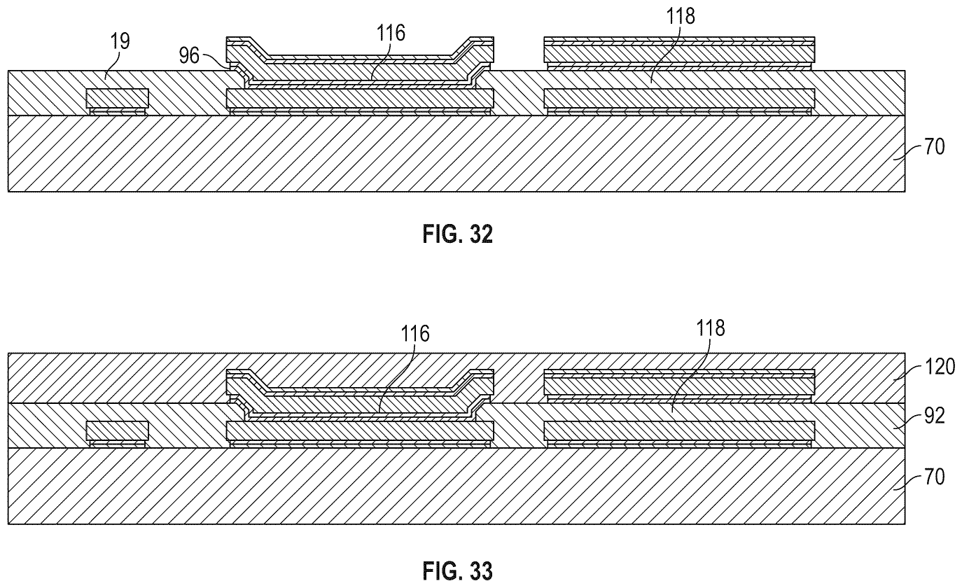

Following electroplating, as illustrated in FIG. 31, the method includes removing the second patterned layer of photoresist from the semiconductor substrate 70, exposing the seed layer 96. FIG. 31 illustrates how the gate pad (lower gate pad) 90 is now separated from the upper gate pad 114 with the polyimide layer 92, which acts as the dielectric for the gate pad structure itself. Referring to FIG. 32, the semiconductor substrate 70 is illustrated following etching of the material of the seed layer 96 from the surface of the polyimide layer 92. This serves to electrically isolate the pad interconnect 116 from the gate interconnect 118. At this point in some method implementations, the semiconductor substrate 70 is ready for singulation into individual semiconductor die in preparation for additional semiconductor packaging operations (if die level packaging is used). If additional substrate-level packaging will be carried out, the interconnects 116 and 118 are ready for the additional processing.

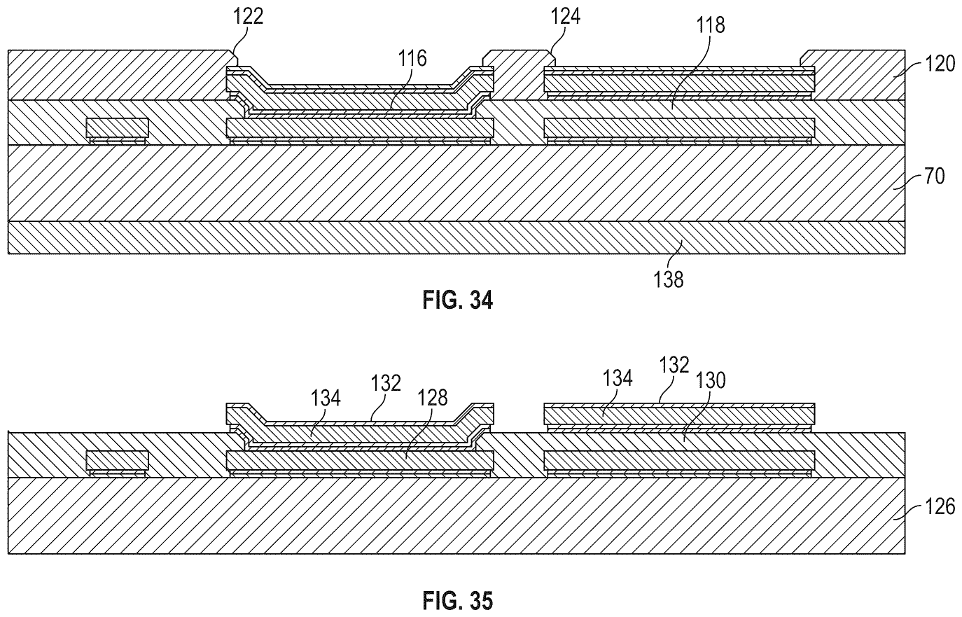

In certain method implementations, the method includes forming a second polyimide layer around the pad interconnect 116 and the gate interconnect 118. Referring to FIG. 33, the semiconductor substrate 70 is illustrated following application of a second polyimide layer 120 over the first polyimide layer 92 using any of the methods disclosed herein for applying a polyimide. In various implementations the material of the second polyimide layer 120 is the same as the material of the first polyimide layer 92; in other implementations the materials are different. FIG. 34 illustrates the semiconductor substrate 70 following patterning of the second layer of polyimide 120 to form openings 122, 124 that expose the upper surface of the pad interconnect 116 and the upper surface of the gate interconnect 118. The use of the second polyimide layer 120 may be particularly helpful if compliant support around the structure of the gate interconnect 118 and the pad interconnect 116 is desired during subsequent packaging operations and/or during operation of the semiconductor device. The use of the second polyimide layer 120 may also be useful when bumps or pillars will be subsequently formed over pad interconnect and/or the gate interconnect 118 where compliant support helps mitigate risks of bump/pillar cracking.

Referring to FIG. 35, an implementation of a semiconductor substrate 126 that includes a pad interconnect 128 and gate interconnect 130 that have a metal layer that is just a silver layer 132 is illustrated. As previously discussed, this implementation is formed by electroplating the silver layer on second copper layer 134. This implementation is designed for use in silver sintering processes where subsequent electrical interconnects are attached using sintering. This implementation may also be used where subsequent electrical interconnects are attached using solders that bond to the silver layer 132. In various implementations, the silver layer 132 may have a thickness of about 4000 angstroms to about 8000 angstroms. In other implementations, the thickness of the silver layer 132 could be as thin as 100 angstroms thick but the thickness will be determined by the degree of oxygen diffusion through the film that will be tolerated as well as how much the silver of the silver layer 132 needs to participate in the solder bond formation. In various interconnect implementations, these solders may have transient liquidus temperatures meaning that the solder initially melts at a first lower temperature to form the bond. After the bond has been formed, the resulting intermetallic compound melts only at a higher second temperature, allowing for the use of additional soldering operations at the original first lower temperature or any temperature below the higher second temperature. This implementation may also be used with wirebonds as the silver surface is wire bondable.

FIG. 36 shows the semiconductor substrate 126 following the addition of a second polyimide layer 136 using a process like that disclosed in FIGS. 33 and 34. For the interconnect implementations that utilize only a silver layer 132 on the second copper layer 134, the replacement of aluminum silicon copper pads with copper and silver layers that have higher melting points, higher electrical conduction properties, higher thermal conductivity, and higher mechanical strength may reduce the issues seen with pad deformation and interlayer dielectric cracking previously mentioned. In various methods of forming the interconnects, the net cost to produce the interconnects may be lower than processes that involve aluminum silicon copper even though the cost of electrolytic plating and polyimide processing may be higher than portions of the aluminum silicon copper process. In various method implementations, the thickness of the tantalum used in the barrier layer can be optimized to absorb interconnect formation forces on the copper nickel gold layer stack caused by heavy wire bonding forces or sintering pressures. Also, the thickness of the copper layer(s) may be optimized depending on the power dissipation requirements of a particular semiconductor device. The thickness of the silver layer may be optimized depending on the continuous operating temperature and/or subsequent interconnect formation requirements (sintering/soldering parameters). A wide variety of interconnect implementations that include silver layers may be formed using the principles disclosed herein.

In the various interconnect implementations disclosed herein that include copper layers, control of oxidation of the copper may be important to ensure proper adhesion/electroplating of adjacent layers and to control electrical characteristics of the ultimate interconnect. Thus, any of the method implementations disclosed herein that involve copper interconnects may employ an organic layer deposited over the copper layer, a thin layer of copper oxide, or a thin layer of another metal which may be about 1 nanometer to about 10 nanometers thick that is deposited using atomic layer deposition. Each of these approaches may control oxidation of the copper layer(s) in the interconnect so that processing occurs predictably even if the semiconductor substrates await processing for different periods of time or in different environmental conditions.

Also, referring to FIG. 34, in any of the method/system implementations disclosed that include copper pads, the method may include forming a backmetal layer 138 on a side of the semiconductor substrate 70. The ability to adjust the backmetal thickness and/or material of the backmetal may help balance stresses on the opposing side of the semiconductor substrate 70 and warpage of the individual semiconductor die singulated form the semiconductor substrate 70. For example, the use of a thicker nickel layer in the backmetal adds stress to the backmetal and the back side of the wafer opposing the side that includes the interconnects 116, 118, which can help reduce the ultimate warpage of the semiconductor die. In various implementations, the backmetal layer may be formed of one layer or multiple layers of the same or dissimilar materials which may be, by non-limiting example, nickel, titanium nickel, titanium nickel vanadium, nickel vanadium silver, nickel vanadium gold, aluminum nickel palladium gold, gold, palladium, aluminum silicon copper, or any combination thereof.

In various methods of forming the copper-containing interconnects disclosed herein, the fabrication processes may be divided in such a way as to prevent copper, gold, and silver contamination of the fabrication location where the front-end layers of the semiconductor devices are formed. Implementations of a method of preventing contamination include processing a semiconductor substrate like any disclosed in this document to a final metallization layer in a first fabrication location. In the first fabrication location, a barrier layer is then formed over the final metallization layer. In various implementations the barrier layer may be any disclosed in this document including tantalum, tantalum nitride, titanium, titanium nitride, titanium tungsten, titanium tungsten nitride, or any combination thereof. The method includes placing the semiconductor substrate into a transporter. In various method implementations, the transporter may be, by non-limiting example, a lot box, a standard mechanical interface (SMIF) pod, a wafer box, a wafer shipper, a front opening unified pod (FOUP), a front opening shipping box (FOSB), a wafer carrier, a wafer jar, a wafer canister, a coin wafer shipper, or any other wafer transporting system.

The method then includes moving the transporter to a second fabrication location separate from the first fabrication location for formation of one or more layers that include copper. The transporters may be moved manually or automatically by workers or robotic transporting systems. In some method implementations the transporters are moved via shipping from the physical location of the first fabrication location to the physical location of the second fabrication location. The method also includes never allowing the transporter to return to the first fabrication location. In this way, any copper/silver/gold contamination on the semiconductor substrate can never enter the first fabrication location.

In various method implementations, never allowing the transporter to return to the first fabrication location includes providing a visual barrier to transport of the transporter back into the first fabrication location. This visual barrier may be a colored line, colored wall, a lighted sign, or any other human perceptible visual indicator that a certain point/line should not be crossed. In other method implementations, never allowing the transporter to return to the first fabrication location includes providing a physical barrier to transport of the transporter back into the first fabrication location. The physical barrier may be a gate, a one-way exit, a wall, a fence, or any other structure that prevents a transporter-sized object from moving past it. In other method implementations, never allow the transporter to return to the first fabrication location may include where the second fabrication location is in a different building than the first fabrication location. The method may also include where the second fabrication location is in a different city/country, etc. than the first fabrication location to prevent transport of the transporter back to the first fabrication location.

The foregoing various method of preventing copper contamination may be able to prevent contamination without incurring millions of dollars to add dedicated fabrication space and dedicated equipment to avoid copper, gold, and/or silver contamination. In other words, existing facilities can be adjusted relatively inexpensively to implement the method implementations which will have the same effect as additional dedicated space in the first fabrication location.

In places where the description above refers to particular implementations of copper pad metallization systems and implementing components, sub-components, methods and sub-methods, it should be readily apparent that a number of modifications may be made without departing from the spirit thereof and that these implementations, implementing components, sub-components, methods and sub-methods may be applied to other copper pad metallization systems.

What is claimed is:

1. A method of forming an interconnect comprising:
forming a barrier layer comprising tantalum over a metallization layer comprised in a semiconductor substrate;
forming a first seed layer over the barrier layer;
forming a first patterned layer of photoresist comprising a plurality of openings over the first seed layer;
forming a first copper layer by electroplating into each opening of the plurality of openings;
removing the first patterned layer of photoresist;
etching the first seed layer and the barrier layer;
patterning a layer of polyimide over the first copper layer to expose a copper pad and form a dielectric layer for a copper gate pad;
forming a second seed layer over the layer of polyimide and the copper pad;
forming a second patterned layer of photoresist comprising a plurality of openings over the second seed layer;
forming a second copper layer by electroplating into the plurality of openings;
forming a metal layer over the second copper layer by electroplating into the plurality of openings;
removing the second patterned layer of photoresist; and
etching the second seed layer to form an interconnect.

2. The method of claim 1, wherein the metal layer is a silver layer.

3. The method of claim 1, wherein the metal layer is a nickel layer and the method further comprises electroplating one of a gold layer, a palladium layer, or a silver layer over the nickel layer.

4. The method of claim 1, further comprising patterning a second layer of polyimide over the interconnect.

5. The method of claim 1, wherein the barrier layer also comprises tantalum nitride.

6. The method of claim 1, wherein the first seed layer comprises copper and the second seed layer comprises titanium tungsten.

7. The method of claim 1, further comprising forming a backmetal layer on a side of the semiconductor substrate opposing the side where the interconnect is located.

8. A semiconductor device comprising:
an interconnect comprising:
a tantalum layer directly coupled with a first copper layer
a titanium tungsten layer directly coupled with the first copper layer;
a second copper layer coupled directly with the titanium tungsten layer;
a metal layer directly coupled to the second copper layer; and
a gate comprising:
a tantalum layer directly coupled with a first copper layer;
a polyimide layer directly coupled over the first copper layer;
a titanium tungsten layer directly coupled over the polyimide layer;
a second copper layer coupled directly with the titanium tungsten layer; and
a metal layer directly coupled to the second copper layer.

9. The device of claim 8, further comprising a gate feed comprising a tantalum layer directly coupled with a first copper layer.

10. The device of claim 8, further comprising a second polyimide layer formed around the metal layer.

11. The device of claim 8, wherein the metal layer comprises only silver.

12. The device of claim 8, wherein the metal layer comprises nickel and one of a gold layer, a palladium layer, or a silver layer are directly coupled to the nickel of the metal layer.

13. The device of claim 9, wherein the layer of polyimide extends over the gate feed.

14. The device of claim 10, wherein the second layer of polyimide extends over the gate feed.

15. The device of claim 8, wherein the tantalum layer is directly coupled over a metallization layer of a semiconductor substrate and the semiconductor substrate comprises a backmetal layer formed thereon.

16. A method of preventing contamination comprising:
processing a semiconductor substrate to a final metallization layer in a first fabrication location;
forming a barrier layer over the final metallization layer in the first fabrication location;
placing the semiconductor substrate in a transporter;
moving the transporter to a second fabrication location separate from the first fabrication location for formation of one or more layers that include copper; and
never allowing the transporter to return to the first fabrication location.

17. The method of claim 16, wherein never allowing the transporter to return to the first fabrication location further comprises providing a visual barrier to transport of the transporter back into the first fabrication location.

18. The method of claim 16, wherein never allowing the transporter to return to the first fabrication location further comprises providing a physical barrier to transport of the transporter back into the first fabrication location.

19. The method of claim 16, wherein never allowing the transporter to return to the first fabrication location further comprises where the second fabrication location is in a different building than the first fabrication location.

20. The method of claim 16. wherein the barrier layer comprises one of tantalum, tantalum nitride, titanium, titanium nitride, titanium tungsten, titanium tungsten nitride, or any combination thereof.
